(19) United States
(12) Patent Application Publication
(10) Pub. No.: US 2023/0309410 A1
(43) Pub. Date: Sep. 28, 2023

(54) Ultrasonic Transducer

(71) Applicant: KROHNE AG, Basel (CH)

(72) Inventor: Willemijn Schipper, Papendrecht (NL)

(21) Appl. No.: 18/189,777

(22) Filed: Mar. 24, 2023

(30) Foreign Application Priority Data
Mar. 25, 2022 (DE) 10 2022 107 092.1

(51) Int. Cl. H10N 30/88; G01H 11/08; G01N 29/22

(52) U.S. Cl. CPC H10N 30/886; G01H 11/08; G01N 29/223

(57) ABSTRACT

An ultrasonic transducer for an ultrasonic flowmeter includes a piezoelectric transducer element arranged between first and second holding elements. The first holding element, the piezoelectric transducer element and the second holding element are arranged one behind the other along a longitudinal axis of the ultrasonic transducer. The pre-tensioning element is on the side of the first holding element facing away from the piezoelectric transducer element. A connecting element is on the side of the pre-tensioning element facing away from the first holding element. The connecting element serves to preload the pre-tensioning element and is connected to the second holding element. In the loaded state of the pre-tensioning element, a force acts on the first holding element and, via the connecting element, on the second holding element in such a way that the first holding element and the second holding element clamp the piezoelectric transducer element.

### TECHNICAL FIELD

The invention relates to an ultrasonic transducer for an ultrasonic flowmeter, having at least one piezoelectric transducer element, having a first holding element and having a second holding element, wherein the at least one piezoelectric transducer element is arranged between the first holding element and the second holding element, and wherein the first holding element, the at least one piezoelectric transducer element and the second holding element are arranged one behind the other along a longitudinal axis.

### BACKGROUND

Ultrasonic transducers of the type in question are known in a multitude from the prior art and are used in ultrasound-based flow or level measurement. The ultrasonic signal is generated by a piezoelectric transducer element.

In many prior art ultrasound transducers, the piezoelectric transducer element is bonded to an ultrasound window through which the ultrasound signals are emitted from the ultrasound transducer into the medium to be measured, or is pressed against the ultrasound window by suitable means. Such an ultrasonic transducer is known, for example, from DE 10 2007 042 663 A1.

In other ultrasonic transducers known from the prior art, the ultrasonic transducers have at least two holding elements between which the piezoelectric transducer element is clamped. Such an ultrasonic transducer is described, for example, in EP 1 181 988 A2. Here, a piezoelectric transducer element is clamped between two holding elements, wherein a tension spring is used for clamping, which is arranged around the piezoelectric transducer element and connects the two holding elements to each other. Each holding element is screwed into the clamping spring. A disadvantage of such a design is that the two holding elements are acoustically coupled to each other directly via the tensioning spring and that, in addition, the shape of the ultrasonic signals generated by the piezoelectric transducer element is influenced.

### SUMMARY

Accordingly, the object of the invention is to provide an ultrasonic transducer for an ultrasonic flowmeter which minimizes the disadvantages known from the prior art.

According to the characterizing portion of the disclosed features, the task is initially and essentially solved in that at least one pre-tensioning element is provided on the side of the first holding element facing away from the piezoelectric transducer element, and that a connecting element is provided on the side of the pre-tensioning element facing away from the first holding element. The connecting element is used for loading the pre-tensioning element and is also connected to the second holding element. In the loaded state of the pre-tensioning element, a force acts on the first holding element and, via the connecting element, on the second holding element such that the first holding element and the second holding element clamp the at least one piezoelectric transducer element.

When it is said that the connecting element is arranged on the side of the pre-tensioning element facing away from the first holding element, it is meant that at least portions or parts of the pre-tensioning element are arranged on the side of the pre-tensioning element facing away from the holding element. Thus, it is not intended that the connecting element is exclusively located on the side of the pre-tensioning element facing away from the first holding element. According to the invention, however, the pre-tensioning element is arranged in the direction of the longitudinal axis of the ultrasonic transducer between the first holding element and the connecting element or regions or parts of the connecting element. According to the invention, the connecting element is connected to the second holding element so that parts of the connecting element extend past the pre-tensioning element and past the first holding element or through the pre-tensioning element and through the first holding element to the second holding element. According to the invention, the connecting element and the second holding element are connected to each other. By this, it is meant that the connecting element and the second holding element are connected to each other at least in the assembled state of the ultrasonic transducer and in particular in the loaded state of the pre-tensioning element. Possible implementations are described further below in connection with designs according to the invention.

The loading of the pre-tensioning element by the connecting element is to implemented by reducing the distance of the pre-tensioning element in the direction of the longitudinal axis of the ultrasonic transducer to the second holding element, thereby compressing the pre-tensioning element in the direction of the longitudinal axis.

In the loaded state, the pre-tensioning element tends to change to the relaxed state, thereby exerting a force on both the connecting element and the first holding element. The two forces are equal in magnitude, but act in opposite directions. Through the connecting element, the force acting on the connecting element is transmitted to the second holding element, so that the force also acts on the second holding element. As a result, the first holding element and the second holding element clamp the piezoelectric transducer element between them. The degree of clamping here depends on the degree of loading of the pre-tensioning element.

An advantage of the implementation of the ultrasonic transducer according to the invention is that all components necessary for the function are arranged along the longitudinal axis of the ultrasonic transducer. In particular, the fact that the pre-tensioning element is not arranged directly in the region of the piezoelectric transducer element, but is arranged at a considerable distance from the piezoelectric transducer element, considerably reduces the influence of the pre-tensioning element on the shape of the radiated ultrasonic signals.

According to the invention, there are various possibilities for the design of the pre-tensioning element. In a particularly preferred design of the ultrasonic transducer according to the invention, it is provided that the pre-tensioning element is designed in the first holding element. This is reduced, for example, by the fact that the pre-tensioning element is implemented by a material reduction of a part of the first holding element or a special shaping of a part of the first holding element. Thus, a spring-like section is implemented in the holding element. The spring-like section is designed on the side of the first holding element facing away from the piezoelectric transducer element.

In a further preferred design, the pre-tensioning element is designed as a separate spring element. All types of spring elements known from the prior art are suitable for this purpose, for example compression springs, disc springs, wave springs or plate springs.

A variation in which a second pre-tensioning element is provided is also particularly preferred. The second pre-tensioning element is preferably arranged adjacent to the first pre-tensioning element in the direction of the longitudinal axis of the ultrasonic transducer. If it is stated that the first pre-tensioning element and the second pre-tensioning element are arranged adjacent to each other, then this can be implemented by the two pre-tensioning elements being arranged directly adjacent to each other, in particular being in touching contact. However, it is also possible for the two pre-tensioning elements to be arranged next to one another at a distance from one another, i.e. for there to be an intermediate space between the two pre-tensioning elements. Particularly preferably, both pre-tensioning elements are designed identically.

According to the invention, the connecting element is provided for loading the pre-tensioning element. At the same time, the connecting element is connected to the second holding element. There are now various ways of implementing the connecting element.

In a particularly preferred design, the connecting element is implemented by a sleeve. In one variation, the sleeve is implemented with a closed surface. In an alternative variation, the sleeve has recesses in its surface, in particular in its lateral surface.

For fastening the sleeve to the second holding element, it is provided in a first variation that the sleeve is connected to the second holding element via additional fastening elements. In one variation, these additional fastening elements are designed as latching elements. For this purpose, a latching recess is provided in the sleeve, and a corresponding latching projection is designed in the second holding element. In a further design, this can also be implemented in reverse, so that the latching recess is implemented in the second holding element and the latching projection in the sleeve.

In a further variation, the additional fastening elements are implemented as screws. Preferably, the sleeve and the second holding element then have corresponding recesses with a mating thread corresponding to the thread of the screw, so that the screws can be screwed into the recesses and thus fasten the sleeve. Since the fastener is designed to load the pre-tensioning element, the sleeve must be fitted in such a way that it loads the pre-tensioning element. Thus, the sleeve encloses the pre-tensioning element as well as the first holding element and the piezoelectric transducer element.

In order to be able to implement fine adjustment of the pre-tensioning element, a particularly preferred variation of the ultrasonic transducer according to the invention is characterized in that the sleeve is designed to be screwed onto the second holding element. For this, the sleeve preferably has an internal thread at its end facing the second holding element, and the second holding element preferably has a corresponding mating thread. Depending on how far the sleeve is screwed onto the second holding element, the pre-tensioning element is loaded to a greater or lesser extent.

In an alternative design of the ultrasonic transducer according to the invention, with which fine adjustment of the pre-tensioning element can also be implemented, it is characterized that the connecting element is designed in a T-shape with a T-roof and a T-rod. The T-shaped connecting element has a thread at its end of the T-bar facing away from the T-roof. The second holding element has a connecting element receptacle with a corresponding mating thread. Moreover, in this design of the ultrasonic transducer according to the invention, it is implemented that the pre-tensioning element, the first holding element and the at least one piezoelectric transducer element each have a recess through which the T-bar of the T-shaped connecting element is passed. The pre-tensioning element is then brought into the loaded state by screwing the T-shaped connecting element into the second holding element. Depending on how far the connecting element is screwed into the second holding element, the bias of the biasing element can be adjusted.

Various variations are provided for implementing the T-roof of the T-shaped connecting element. In a first variation, the T-roof is configured as a closed disc. In an alternative variation, the T-roof is implemented by a disc having recesses. In all variations, the T-roof is designed in such a way that uniform loading of the pre-tensioning element is implemented.

In an alternative variation, the connecting element is implemented by a connecting rod and a nut. The connecting rod is connected to the second holding element. In such a design, the pre-tensioning element, the first holding element and the at least one piezoelectric transducer element also each have a recess through which the connecting rod is guided. At its end facing away from the second holding element, the connecting rod has a thread onto which the nut can be screwed. Screwing the nut onto the threaded rod brings the pre-tensioning element into the loaded state. The degree of loading can also be finely adjusted here by the degree to which the nut is screwed onto the connecting rod.

As explained, the connecting rod is connected to the second holding element. In a first variation, the connecting rod is non-detachably connected to the second holding element. This is implemented, for example, by welding the connecting rod and the second holding element together. In an alternative design, the connecting rod and the second holding element are manufactured in one piece, i.e. are made from a single workpiece. When reference is made to an undetachable connection, it is meant that the connection is not detachable without destroying the arrangement, in particular that special force is required to detach the connection.

In an alternative variation, the connection between the second holding element and the connecting element is designed to be detachable. Here, in one variation, it is provided that the connecting rod has a thread at its end facing the second holding element and that the second holding element has a recess with a mating thread, so that the connecting rod can be screwed to into the holding element. In an alternative variation, the holding element and the connecting rod are connected to each other by a bayonet lock. In a third variation, the connecting rod and the second holding element are connected to each other by a snap-in connection.

### BRIEF DESCRIPTION OF THE DRAWINGS

In detail, there are now a large number of possibilities for designing and further developing the ultrasonic transducer according to the invention. In this regard, reference is made to the description of particularly preferred embodiments in conjunction with the drawings.

FIG. 1 illustrates an external view of a first variation of an ultrasonic transducer.

FIG. 2 illustrates a sectional view of the ultrasonic transducer shown in FIG. 1.

FIG. 3 illustrates a sectional view of the first holding element of the ultrasonic transducer shown in FIG. 2.

FIG. 4 illustrates a sectional view of a second variation of an ultrasonic transducer.

FIG. 5 illustrates a sectional view of a third variation of an ultrasonic transducer.

FIG. 6 illustrates a sectional view of a fourth variation of an ultrasonic transducer.

FIG. 7 illustrates a sectional view of a fifth variation of an ultrasonic transducer.

### DETAILED DESCRIPTION

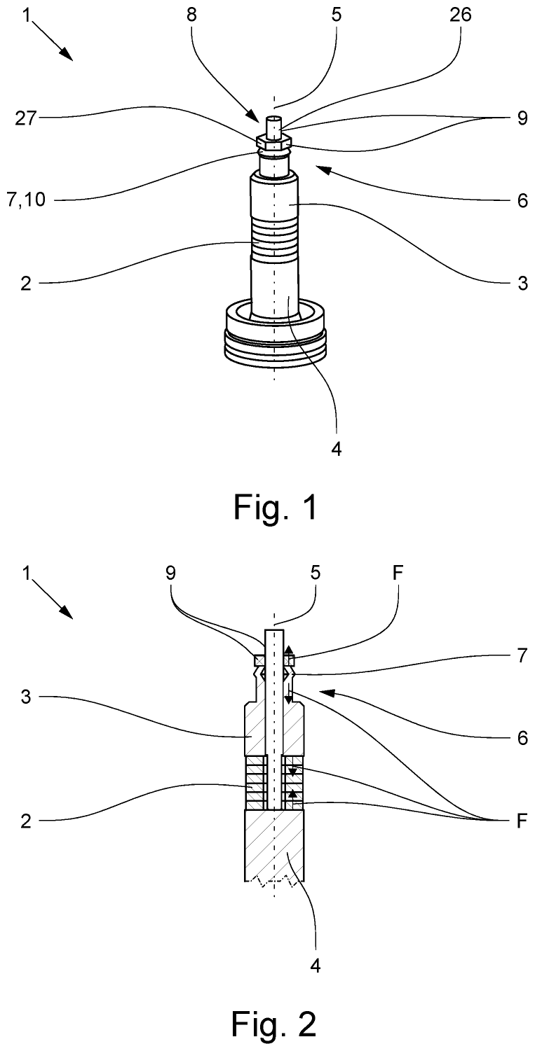

FIG. 1 shows an external view of an ultrasonic transducer 1 for an ultrasonic flowmeter. The ultrasonic transducer 1 has at least one piezoelectric transducer element 2. In the illustrated embodiment, the ultrasonic transducer 1 has a total of six piezoelectric transducer elements 2. In addition, the ultrasonic transducer 1 has a first holding element 3 and a second holding element 4, wherein the piezoelectric transducer elements 2 are arranged between the first holding element 3 and the second holding element 4. The first holding element 3, the piezoelectric transducer elements 2 and the second holding element 4 are arranged one behind the other along a longitudinal axis 5 of the ultrasonic transducer 2. On its side 6 facing away from the piezoelectric transducer elements 2, the first holding element 3 has a pre-tensioning element 7. On the side 8 of the pre-tensioning element 7 facing away from the first holding element 3, a connecting element 9 is provided. The connecting element 9 serves to load the pre-tensioning element 7 and is connected to the second holding element 4. The connection of the connecting element 9 and the second holding element 4 is not visible in FIG. 1, but is apparent in the sectional view through the ultrasonic transducer of FIG. 1 shown in FIG. 2.

FIG. 2 shows a sectional view through the ultrasonic transducer 1 of FIG. 1. The pre-tensioning element 7 is loaded by the connecting element 9. In the loaded state, which is shown in FIG. 2, a force F acts on the first holding element 3 and via the connecting element 9 on the second holding element 4 in such a way that the first holding element 3 and the second holding element 4 clamp the piezoelectric transducer elements 2. In FIG. 2, the acting forces are indicated by force arrows. Due to the fact that the pre-tensioning element 7 strives to go into its relaxed state, a force F acts on the connecting element 9. An opposite force F acts on the first holding element 3. The force acting on the connecting element 9 is transmitted to the second holding element 4 due to the connection of the connecting element 9 and the second holding element 4. In the area of the piezoelectric transducer elements 2, a force F thus acts on the second transducer element, which strives to pull the transducer element upwards, and an opposite force F acts on the second holding element 3, which strives to pull the holding element 3 downwards. Accordingly, the piezoelectric transducer elements 2 are clamped between the first holding element 3 and the second holding element 4.

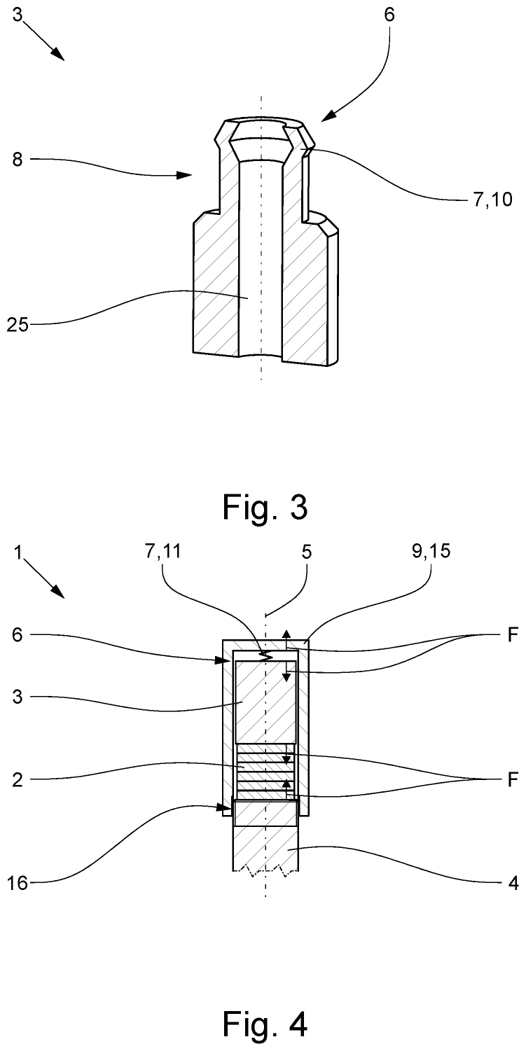

In the illustrated embodiment of FIG. 2, the pre-tensioning element 7 is designed in the first holding element 3. The first holding element 3 of FIG. 2 is also shown in sectional view in FIG. 3. The first holding element 3 is cylindrical in overall shape. In its upper region, namely on the side 6 facing away from the piezoelectric transducer elements 2, the second holding element 4 has a material reduction. This implements a pre-tensioning element 7 in the form of a spring element. The wall thickness of the first holding element 3 is significantly reduced in the upper region 6, and the first holding element 3 is compressible in this upper region 6 in the longitudinal direction 5 of the ultrasonic transducer 1.

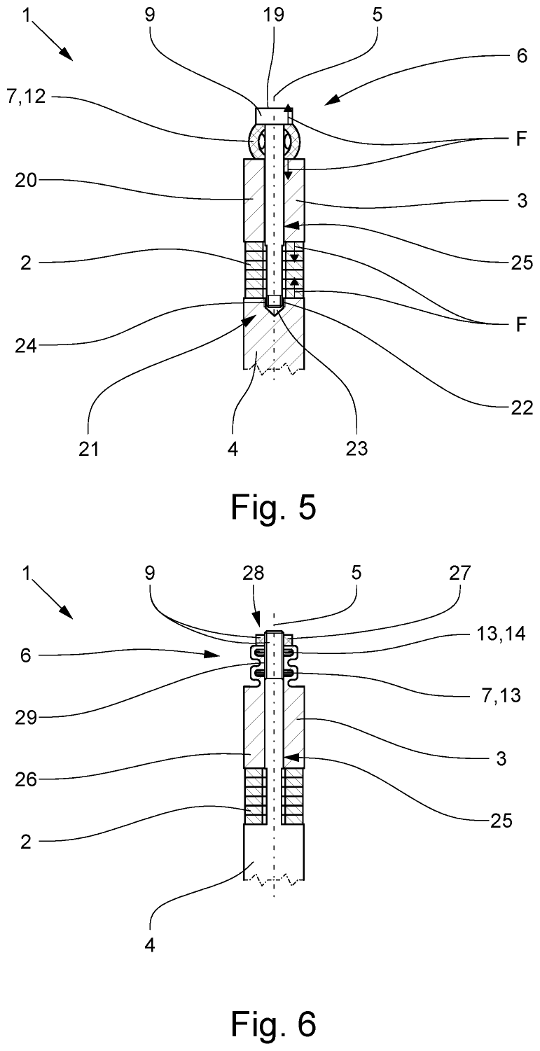

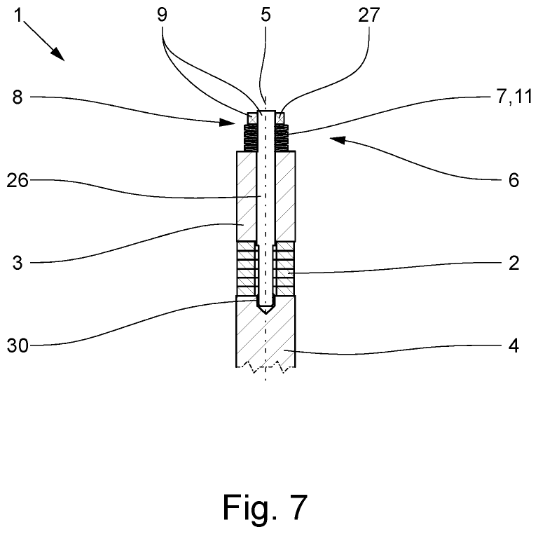

In the further figures, the pre-tensioning elements 7 are shown in alternative embodiments. In FIG. 7, for example, the pre-tensioning element 7 is implemented by a compression spring 11. In FIG. 5, the pre-tensioning element 7 is implemented as a disk spring 12. FIG. 6 shows an illustration in which the pre-tensioning element 7 is designed as a plate spring 13. FIG. 6 also shows that the ultrasonic transducer 1 has a second pre-tensioning element 14. This pre-tensioning element 14 is also implemented as a plate spring 13. The first pre-tensioning element 7 and the second pre-tensioning element 14 are arranged adjacent to each other, but spaced apart from each other, along the longitudinal axis 5 of the ultrasonic transducer 1.

The figures also show various designs of the connecting element 9. In the embodiment shown in FIG. 4, the connecting element 9 is implemented by a sleeve 15. The sleeve 15 is connected to the second holding element 4 via a screw connection 16. For this, an internal thread 17 is designed on the sleeve 15 and a corresponding external thread 18 is designed on the second holding element 4. The sleeve 15 is screwed onto the second holding element 4. Screwing on compresses the pre-tensioning element 7, which in the embodiment shown is implemented as a compression spring 11. In alternative embodiments not shown, the sleeve 15 can be snapped onto the second holding element or, for example, connected to the second holding element with additional fastening elements in the form of screws.

FIG. 5 shows a further embodiment of an ultrasonic transducer 1 with an alternative connecting element 9. In the embodiment shown, the connecting element 9 is implemented in a T-shape and has a T-roof 19 and a T-rod 20. At its end 21 facing away from the T-roof 19, a thread 22 is designed on the T-rod 20. The second holding element 4 has a connecting element receptacle 23 with a corresponding mating thread 24, so that the T-bar 20 can be screwed into the connecting element receptacle 23. Both the pre-tensioning element 7 and the first holding element 3 and the piezoelectric transducer elements 2 each have a recess 25 through which the T-bar 20 of the T-shaped connecting element 9 is passed. By screwing the T-shaped connecting element 9 into the second holding element 4, the pre-tensioning element 7 is brought into the loaded state.

Further embodiments of the connecting element 9 are implemented in FIG. 6 and FIG. 7. In FIG. 6 and also in FIG. 7, the connecting element 9 is implemented by a connecting rod 26 and a nut 27. The connecting rod 26 is connected to the second holding element 4. Also in this embodiment, the pre-tensioning element 7, the first holding element 3 and the piezoelectric transducer elements 2 each have a recess 25 through which the connecting rod 26 is guided. At its end 28 facing away from the second holding element 4, the connecting rod 26 has a thread 29 onto which the nut 27 can be screwed. Screwing the nut 27 onto the connecting rod 26 brings the pre-tensioning element 7 or, in the design shown in FIG. 6, the pre-tensioning elements 7 and 14, into the loaded state.

In FIG. 6, the connecting rod 26 is non-detachably connected to the second holding element 4, namely in the embodiment designed integrally with the second connecting element 4. In contrast, in the embodiment of FIG. 7, the connecting rod 26 is detachably connected to the second holding element 4. In the example shown, this is implemented by a screw connection 30. Further possibilities not shown are, for example, snap-in connections or bayonet connections.

1. An ultrasonic transducer for an ultrasonic flowmeter, comprising:
at least one piezoelectric transducer element;
a first holding element;
a second holding element;
wherein the at least one piezoelectric transducer element is arranged between the first holding element and the second holding element;
wherein the first holding element, the at least one piezoelectric transducer element and the second holding element are arranged one behind the other along a longitudinal axis of the ultrasonic transducer;
wherein at least one pre-tensioning element is provided on the side of the first holding element facing away from the piezoelectric transducer element;
wherein a connecting element is provided on the side of the pre-tensioning element facing away from the first holding element, wherein the connecting element serves to preload the pre-tensioning element and is connected to the second holding element; and
wherein, in the loaded state of the pre-tensioning element, a force acts on the first holding element and, via the connecting element, on the second holding element in such a way that the first holding element and the second holding element clamp the at least one piezoelectric transducer element.

2. An ultrasonic transducer according to claim 1, wherein the pre-tensioning element is designed in the first holding element; and
pre-tensioning element is implemented by a material reduction of the first holding element.

3. The ultrasonic transducer according to claim 1, wherein the pre-tensioning element is designed as a compression spring, disc spring, wave spring or plate spring.

4. The ultrasonic transducer according to claim 1, wherein at least one second pre-tensioning element is provided;
wherein the first pre-tensioning element and the second pre-tensioning element are arranged adjacent to one another in the direction of the longitudinal axis of the ultrasonic transducer; and
wherein the first pre-tensioning element and the second pre-tensioning element are designed identically.

5. The ultrasonic transducer according to claim 1, wherein the connecting element is implemented by a sleeve; and
wherein the sleeve can be connected to the second holding element via additional fastening elements or the sleeve can be screwed onto the second holding element, so that the pre-tensioning element is brought into the loaded state by the latching or by the screwing on of the sleeve.

6. The ultrasonic transducer according to claim 1, wherein the connecting element is designed in a T-shape with a T-roof and a T-bar;
wherein the T-shaped connecting element has a thread at end of the T-bar facing away from the T-roof;
wherein the second holding element has a connecting-element receptacle with a corresponding mating thread;
wherein the pre-tensioning element, the first holding element and the at least one piezoelectric transducer element each have a recess through which the T-bar of the T-shaped connecting element is passed; and
wherein the pre-tensioning element is brought into the loaded state by screwing the T-shaped connecting element into the second holding element.

7. The ultrasonic transducer according to claim 1, wherein the connecting element is implemented by a connecting rod and a nut;
wherein the connecting rod is connected to the second holding element;
wherein the pre-tensioning element, the first holding element and the at least one piezoelectric transducer element each have a recess through which the connecting rod is passed;
wherein, at an end facing away from the second holding element, the connecting rod has a thread onto which the nut can be screwed; and
wherein the pre-tensioning element is brought into the loaded state by screwing the nut onto the connecting rod.

8. The ultrasonic transducer according to claim 7, wherein the connecting rod is welded to the second holding element or is designed integrally with the second holding element.

9. The ultrasonic transducer according to claim 7, wherein the connecting rod is detachably connected to the second holding element by a screw connection, a snap-in connection or a bayonet connection.
